(19) United States
(12) Patent Application Publication
(10) Pub. No.: US 2013/0049075 A1
(43) Pub. Date: Feb. 28, 2013

(54) SOLID-STATE IMAGING DEVICE AND METHOD FOR MANUFACTURING THE SAME

(71) Applicant: An Do KI, Seoul (KR)

(72) Inventor: An Do KI, Seoul (KR)

(73) Assignee: Dongbu HiTek Co., Ltd., Seoul (KR)

(21) Appl. No.: 13/545,313

(22) Filed: Jul. 10, 2012

(30) Foreign Application Priority Data
Aug. 23, 2011 (KR) 10-2011-0084056

(51) Int. Cl. H01L 27/148; H01L 31/18

(52) U.S. Cl. 257/231; 438/60; 257/E27.15; 257/E31.054

(57) ABSTRACT

A solid-state imaging device having a protective wiring inserted between adjacent pixel pairs so that the generation of electrical charges caused by a voltage variation in adjacent pixel pairs may be restrained, and a method for manufacturing the same. A solid-state imaging device with an additional protective wiring may be provided between pixel pairs to restrain the generation of electric charges within one of the pixel pairs caused by a voltage variation in the other pixel pair. A method for manufacturing a solid-state imaging device with an additional protective wiring which is provided between pixel pairs to restrain the generation of electric charges within one of the pixel pairs caused by a voltage variation in the other pixel pair.

The present application claims priority under 35 U.S.C. 119 to Korean Patent Application No. 10-2011-0084056 (filed on Aug. 23, 2011), which is hereby incorporated by reference in its entirety.

### BACKGROUND

Semiconductor devices for sensing a physical quantity distribution may be configured with a plurality of unit components (e.g. pixels) which may be responsive to external electromagnetic waves such as light, radioactive rays and so on, and may be widely used in a variety of fields.

In some circumstances, such as image devices, solid-state imaging devices may be used in the form of charge coupled devices (CCDs), metal oxide semiconductor (MOS) image sensors and complementary metal-oxide semiconductor (CMOS) image sensors to sense light corresponding to one of physical quantities (e.g. electro-magnetic waves). Such solid-state imaging devices may read a physical quantity distribution from electrical signals which may be obtained through converting operations of the unit components (e.g. pixels).

Moreover, among the solid-state image sensing devices, there may be an active solid-state imaging devices including pixels configured with active pixel sensors (APSs), which may also be called “gain cells”. The active pixel sensor may include a drive transistor for the amplification which may be provided in a pixel signal generator for deriving a pixel signal from electrical charges generated in an electrical charge generator. In many circumstances, most CMOS image sensors may have the pixel configuration as described above.

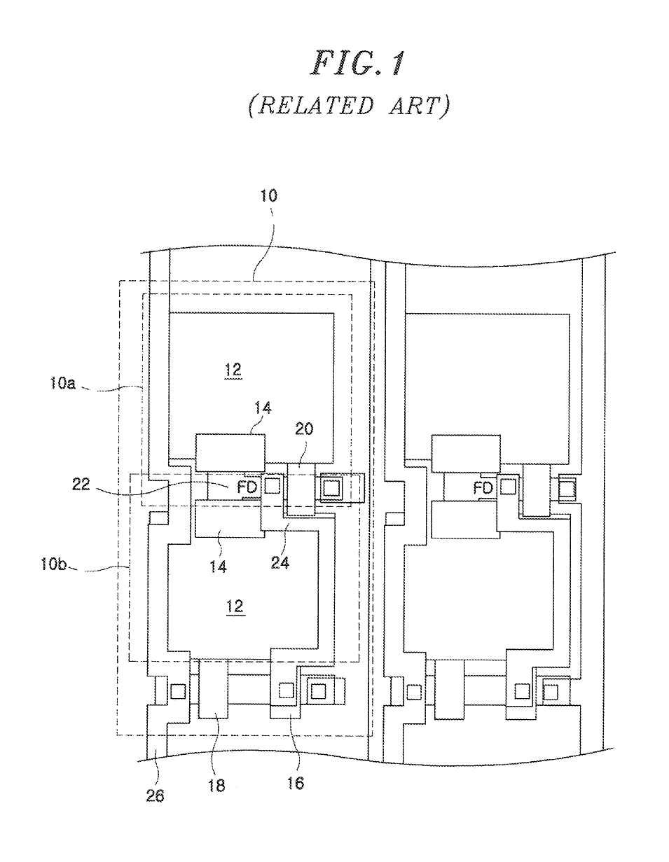

The following is a description of a unit pixel of the CMOS imaging device, in accordance with the related art. FIG. 1 is a planar view showing the layout of a pixel pair of a solid-state imaging device (i.e., a CMOS image sensor), in accordance with the related art.

As shown in FIG. 1, a pixel pair 10 may be configured with two pixels 10a and 10b which may be arranged adjacently to each other in a column direction (i.e., y-direction). Each of the pixels 10a and 10b may include a photodiode 12 for generating electrical charges, and a signal output unit having transistors for deriving an electrical signal from the electrical charge to output the electrical signal. The signal output unit may include: (1) A transfer transistor which may have a transfer gate 14 and reads the electrical charge generated in the photodiode 12. (2) A drive transistor which may have a drive gate 16 and may convert the read electrical charge into a pixel signal. (3) A select transistor which may have a select gate 18 and may select a pixel to be used for readout. (4) A reset transistor which may have a reset gate 20 and may reset the electrical charge. (5) A floating diffusion region 22.

The pixels 10a and 10b may share the floating diffusion region 22 and the reset and drive transistors with each other. The floating diffusion region 22 may be connected to the drive gate 16 through a local wiring 24. The select transistor may select a pixel pair 10 to output a signal voltage through an output wiring 26.

In the solid-state imaging device of the related art, when a voltage applied to the output wiring of adjacent pixel pair may be changed, the quantity of electrical charges induced on the local wiring may change accordingly due to a coupling, which may result in a change of the output voltage of the adjacent pixel pair to thereby distort an image sensed by the solid-state imaging device.

### SUMMARY

Embodiments relate to a solid-state imaging device. Some embodiments particularly relate to a solid-state imaging device which may have a protective wiring inserted between adjacent pixel pairs so that the generation of electrical charges caused by a voltage variation in adjacent pixel pairs may be restrained, and a method for manufacturing the same.

Embodiments provide a solid-state imaging device with an additional protective wiring provided between pixel pairs to restrain the generation of electric charges within one of the pixel pairs caused by a voltage variation in the other pixel pair. Embodiments relate to a method for manufacturing a solid-state imaging device with an additional protective wiring provided between pixel pairs to restrain the generation of electric charges within one of the pixel pairs caused by a voltage variation in the other pixel pair. Embodiments relate to a solid-state imaging device including at least one of: (1) A plurality of pixel pairs, each pair having two pixels that may be closely arranged in a column direction, wherein each pixel within each of the pixel pairs may include a photodiode and a transfer transistor and has a floating diffusion region, a reset transistor, and a drive transistor may be shared with the other pixel. (2) A protective wiring through which a common voltage may be supplied, wherein the pixel pairs are isolated from each other by the protective wiring. Preferably, the protective wiring may be connected to a drain electrode of the reset transistor and a drain electrode of the drive transistor to which the common voltage may be supplied.

Embodiments relate to a method of manufacturing a solid-state imaging device including a plurality of pixel pairs, each pair having two pixels arranged in a column direction, the method including at least one of: (1) Forming transfer, reset and drive gates on regions of a semiconductor substrate. (2) Forming a photodiode in a region adjacent to one edge of the transfer gate in the semiconductor substrate. (3) Forming a floating diffusion region between the transfer gate and the reset gate in the semiconductor substrate. (4) Performing an impurity ion injection process on two opposite edges of the transfer, reset and drive gates to form sources and drains. (5) Forming a protective wiring configured to connect the drain of the drive gate and the drain of the reset gate.

In embodiments, the forming of the protective wiring includes at least one of: (1) Forming contact holes which expose the drains of the reset and drive gates. (2) Filling a metal material in the contact holes to form contacts. (3) Forming protective wirings to connect the drains of the reset and drive gates.

### DRAWINGS

The above and other objects and features of embodiments may become apparent from the following description of embodiments given in conjunction with the accompanying drawings, in which:

Example FIG. 1 is a planar view showing the layout of pixel pairs of a solid-state imaging device (e.g. a CMOS image sensor), in accordance with the related art.

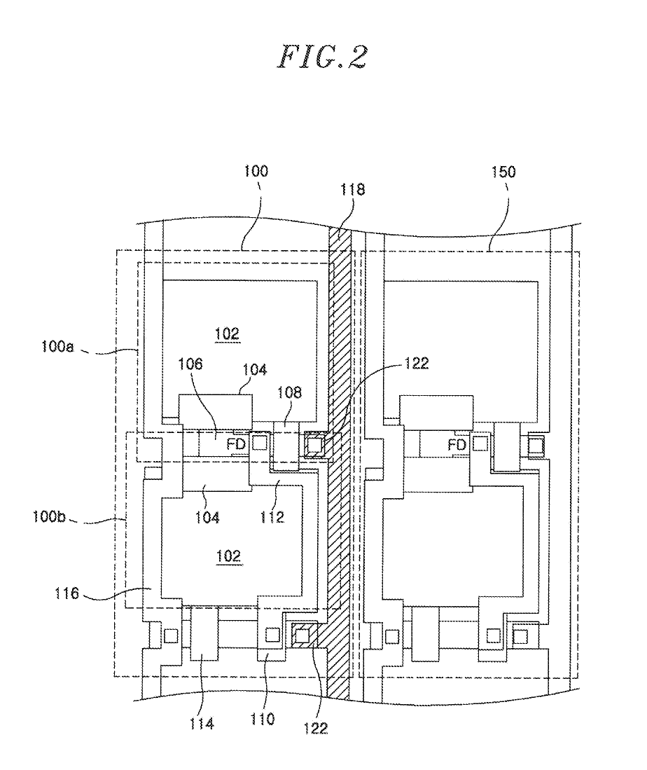

Example FIG. 2 is a planar view showing the layout of pixel pairs of a solid-state imaging device (e.g. a CMOS image sensor), in accordance with the embodiments.

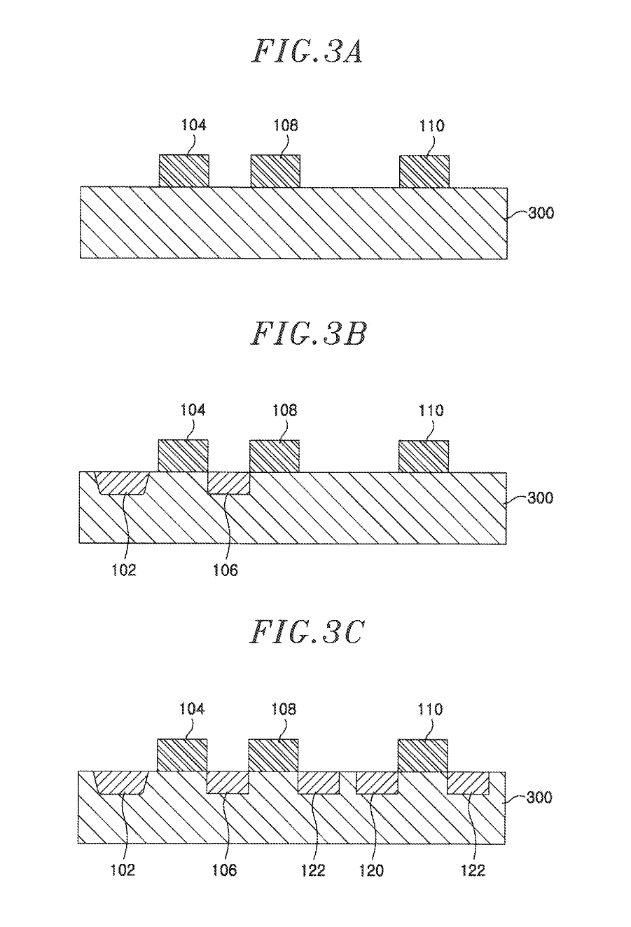

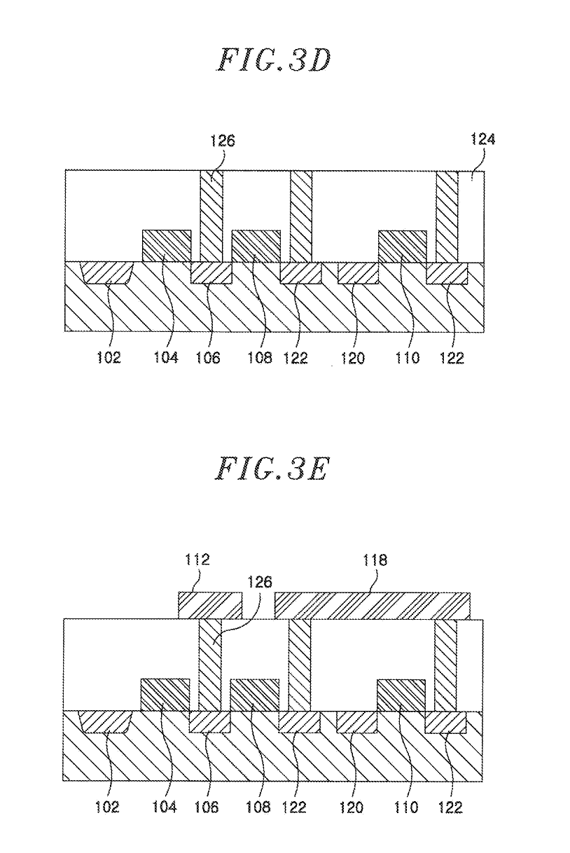

Example FIGS. 3A to 3E are cross-sectional views illustrating a sequential process of a method for manufacturing a solid-state imaging device, in accordance with embodiments.

### DESCRIPTION

Embodiments relate to a structure of a solid-state imaging device with an additional protective wiring which may be provided between pixel pairs to restrain the generation of electric charges within one of the pixel pairs caused by a voltage variation in the other pixel pair due to a coupling between the adjacent pixel pairs when data is output, and a method for manufacturing the same.

Example FIG. 2 is a planar view showing the layout of pixel pairs of a solid-state imaging device (e.g. a CMOS image sensor), in accordance with the embodiments. A pixel pair 100 may include two pixels 100a and 100b adjacently arranged to each other in a column direction (i.e., y-direction). Each of the two pixels 100a and 100b may include a photodiode 102 and a transfer gate 104. A floating diffusion region (FD) 106, a reset gate 108, a drive gate 110 and a select gate 114 are shared by both the pixels 100a and 100b.

The photodiode 102 may generate electrons in response to a light signal applied thereto. A transfer transistor having the transfer gate 104 may transfer the electrons generated in the photodiode 104 to the floating diffusion region 106. A drive transistor having the drive gate 110 may be connected to the floating diffusion region 106 through a local wiring 112 and may amplify an electric current of the floating diffusion region 106. A select transistor having the select gate 114 may select the pixel pair 100 to output a signal voltage through an output wiring 116.

The pixel pair 100 of the solid-state sensing device in accordance with the embodiments may be isolated from an adjacent pixel pair 150 by means of a protective metal wiring 118. More specifically, the protective metal wiring 118 may be connected to a reference voltage as a fixed voltage and separates the adjacent pixel pairs 100 and 150 from each other by applying the reference voltage to the respective pixel pairs. For example, a common voltage Vdd may be preferable to be used as the fixed voltage.

Further, drains 122 of the drive gate 110 and the reset gate 108 may be connected with each other by the protective metal wiring 118 through which the common voltage Vdd may be supplied to the drains 122 as a fixed voltage. In accordance with the embodiments having the structure of the pixel pairs of the solid-state imaging device, the protective metal wiring 118 formed between the pixel pairs 100 and 150 may serve to restrain the generation of electric charges within the pixel pair 100, which may be caused by a voltage variation on the output wiring of the pixel pair 150 adjacent to the pixel pair 100.

A method for manufacturing a solid-state imaging device having the above-mentioned configuration will now be explained with reference to FIGS. 3A to 3E. FIGS. 3A to 3E are cross-sectional views illustrating a sequential process of manufacturing a solid-state imaging device in accordance with embodiments.

As shown in example FIG. 3A, in accordance with embodiments, portions of a semiconductor substrate 300 comprised of silicon or the like may be etched and an insulation material may be filled into the etched portions of the semiconductor substrate 300 to form a shallow french isolation layer (not shown) which may define active regions. Subsequently, a gate formation process may be performed on the active regions to form a transfer gate 104, a reset gate 108 and a drive gate 110 on the active regions. More specifically, the transfer gate 104, the reset gate 108 and the drive gate 110 may be prepared by forming a conductive material, such as polysilicon, on the active regions and etching the conductive material. In embodiments, a select gate 114 may be formed along with the formation of the gates 104, 108, and 110.

In embodiments, a photodiode 102 may be formed by performing an ion injection process on a portion of the semiconductor substrate 300, as shown in FIG. 3B. In embodiments, the photodiode 102 may be formed by injecting ions for the formation of the photodiode into the region adjacent to one edge of the shallow trench isolation layer (e.g. the region adjacent to one edge of the transfer gate 104 on the semiconductor substrate 300). Next, a floating diffusion region 106 may be formed between the transfer gate 104 and the reset gate 108 through another ion injection process.

As shown in example FIG. 3C, in accordance with embodiments, an impurity ion injection process may be performed using the transfer gate 104, the reset gate 108 and the drive gate 110 as masks to form sources 120 and drains 122 within regions of adjacent to two opposite edges of the transfer gate 104, the reset gate 108 and the drive gate 110 on the semiconductor substrate 300. Therefore, a transfer transistor, a reset transistor and a drive transistor may be formed through the above-mentioned processes.

In embodiments, as shown in example FIG. 3D, an interlayer insulation layer 124 may be formed on the entire surface of the semiconductor substrate 300 provided with the transfer transistor, the reset transistor and the drive transistor and an etching process may be then formed, to thereby form contact holes for exposing a part of the floating diffusion region 106, a part of the drain 122 of the reset transistor, and a part of the drain 122 of the drive transistor. Subsequently, a metal material may be filled in the contact holes to form contacts 126.

In embodiments, as shown in example FIG. 3E, a metal wiring formation process may be performed to form a local wiring 112 which may connect the floating diffusion region 106 and the drive gate 110 (not shown); and a protective metal wiring 118 which may connect the drain 122 of the reset transistor and the drain 122 of the drive transistor. The protective metal wiring 118 may serve to prevent the generation of a coupling capacitance in the local wiring 112 due to a voltage variation on an output wiring of an adjacent pixel pair, in accordance with embodiments.

In accordance with embodiments, a solid-state imaging device having an additional protective metal wiring formed between the adjacent pixel pairs may restrain the generation of electric charges in one of the pixel pairs even though the voltage variation on the output wiring of the other one. Accordingly, in embodiments, a distortion generation in the image sensed by the solid-state imaging device may be reduced. It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a plurality of pixel pairs, wherein each pixel within each of the pixel pairs comprises a photodiode and a transfer transistor; and
a protective wiring, wherein the pixel pairs are isolated from each other by the protective wiring.

2. The apparatus of claim 1, wherein the apparatus is an imaging device.

3. The apparatus of claim 2, wherein the imaging device is a solid-state imaging device.

4. The apparatus of claim 1, wherein each pair of said plurality of pixel pairs has two pixels that are arranged substantially adjacent in a column direction.

5. The apparatus of claim 1, a common voltage may be supplied through the protective wiring.

6. The apparatus of claim 5, wherein the common voltage is a fixed voltage.

7. The apparatus of claim 1, wherein each of the pixel pairs comprises a floating diffusion region, a reset transistor and a drive transistor shared between two pixels of said each of the pixel pairs.

8. The apparatus of claim 7, wherein the protective wiring is electrically coupled to a drain electrode of the reset transistor and a drain electrode of the drive transistor to supply the common voltage to the drain electrode of the reset transistor and the drain electrode of the drive transistor.

9. A method, the method comprising:
forming a transfer gate, a reset gate, and a drive gate on regions of a semiconductor substrate;
performing an impurity ion injection process on two opposite edges of the reset gate and the drive gate to form a source and drain associated with the reset gate and a source and drain associated with the drive gate; and
forming a protective wiring configured to electrically couple the drain of the drive gate and the drain of the reset gate.

10. The method of claim 9, wherein the method is a method of manufacturing a solid-state imaging device including a plurality of pixel pairs, each pair having two pixels arranged in a column direction.

11. The method of claim 9, comprising forming a photodiode in a region adjacent to one edge of the transfer gate in the semiconductor substrate.

12. The method of claim 9, comprising forming a floating diffusion region between the transfer gate and the reset gate in the semiconductor substrate.

13. The method of claim 9, wherein said impurity ion injection process is performed on two opposite edges of the transfer gate to form a source and a drain associated with the transfer gate.

14. The method of claim 9, wherein said forming the protective wiring comprises forming contact holes which expose the drains of the reset and drive gates.

15. The method of claim 14, comprising filling a metal material in the contact holes to form contacts.

16. The method of claim 14, comprising forming protective wirings to connect the drain of the reset gate and the drain of the drive gate.
